(19) United States
(12) Patent Application Publication
(10) Pub. No.: US 2024/0291450 A1
(43) Pub. Date: Aug. 29, 2024

(54) AMPLIFIER CIRCUIT, POWER AMPLIFIER CIRCUIT, AND COMMUNICATION DEVICE

(71) Applicant: Murata Manufacturing Co., Ltd., Kyoto (JP)

(72) Inventor: Makoto TABEI, Kyoto (JP)

(21) Appl. No.: 18/586,938

(22) Filed: Feb. 26, 2024

(30) Foreign Application Priority Data
Feb. 27, 2023 (JP) 2023-028398

(51) Int. Cl. H03F 3/24; H03F 1/56

(52) U.S. Cl. CPC H03F 3/245; H03F 1/56; H03F 2200/387

(57) ABSTRACT

An amplifier circuit includes: a second FET connected, together with a first FET, between a power supply and a reference potential; a first voltage divider resistor circuit; a first switch element; a second voltage divider resistor circuit; a third voltage divider resistor circuit; and a second switch element. The first FET and the second FET have their adjacent drains and sources connected. Each resistance value of the second voltage divider resistor circuit is greater than each resistance value of the first voltage divider resistor circuit. Each resistance value of the third voltage divider resistor circuit is less than each resistance value of the second voltage divider resistor circuit. The second voltage divider resistor circuit and the third voltage divider resistor circuit have an identical voltage division ratio.

### CROSS REFERENCE TO RELATED APPLICATION

This application claims priority from Japanese Patent Application No. 2023-028398 filed on Feb. 27, 2023. The content of this application is incorporated herein by reference in its entirety.

### BACKGROUND ART

The present disclosure relates to an amplifier circuit, a power amplifier circuit, and a communication device.

An amplifier circuit in which transistors, which are amplifier elements, are connected in a vertical stack, is known (for example, Japanese Patent No. 5420768). In the amplifier circuit of Japanese Patent No. 5420768, transistors at multiple stages are provided between a power supply and a reference potential. Moreover, among the transistors at multiple stages, a signal to be amplified is input to the base of the transistor closest to the ground potential. Then, among the transistors at multiple stages, a load is connected between the transistor closest to the power supply and the power supply.

### BRIEF SUMMARY

By the way, a communication device that utilizes multiple types of frequency bands may have an amplifier circuit corresponding to each frequency band. For example, an amplifier circuit corresponding to a high frequency band (high-band) and an amplifier circuit corresponding to a medium frequency band (mid-band) may be provided in or on a mobile communication device. The operating timings of those amplifier circuits are different from each other. If those amplifier circuits are connected to a common power supply line, the power supply voltage continues to be applied even when an amplifier circuit is not performing signal amplification (that is, when in a standby state). Leakage current may be generated by the power supply voltage applied as above. There is an issue that this leakage current consumes power wastefully.

The present disclosure provides an amplifier circuit, a power amplifier circuit, and a communication device capable of suppressing power consumption due to leakage current.

An amplifier circuit according to an aspect of the present disclosure includes: an input terminal to which a signal to be amplified is input; a first FET having a gate to which the signal input to the input terminal is applied; a second FET connected, together with the first FET, between a power supply and a reference potential; an output terminal provided between the second FET and a load to output an amplified signal; a first voltage divider resistor circuit that divides a potential difference between the power supply and the reference potential, and generates a bias to be applied to a gate of the second FET; a first switch element provided between the first voltage divider resistor circuit and the power supply and for turning on/off an electrical connection between the power supply and the first voltage divider resistor circuit; a second voltage divider resistor circuit that divides a potential difference between the power supply and the reference potential, and generates a bias to be applied to the gate of the second FET; a third voltage divider resistor circuit that divides a potential difference between the power supply and the reference potential, and generates a bias to be applied to the gate of the second FET; and a second switch element provided between the third voltage divider resistor circuit and the power supply and for turning on/off an electrical connection between the power supply and the third voltage divider resistor circuit. The first FET and the second FET have their adjacent drains and sources connected. A resistance value of each of resistors included in the second voltage divider resistor circuit is greater than a resistance value of each of resistors included in the first voltage divider resistor circuit. A resistance value of each of resistors included in the third voltage divider resistor circuit is less than the resistance value of each of the resistors included in the second voltage divider resistor circuit. A voltage division ratio of the resistors included in the second voltage divider resistor circuit and a voltage division ratio of the resistors included in the third voltage divider resistor circuit are identical.

A power amplifier circuit according to an aspect of the present disclosure in which the above-described amplifier circuit serves as a driver-stage amplifier circuit, further includes a power-stage amplifier circuit, with output of the driver-stage amplifier circuit serving as input.

A communication device according to an aspect of the present disclosure includes a plurality of the above-described power amplifier circuits, wherein the plurality of the power amplifier circuits selectively perform amplification operation based on a voltage supplied by a common power supply.

According to the present disclosure, power consumption due to leakage current can be suppressed.

### BRIEF DESCRIPTION OF THE DRAWINGS

FIG. 1 is a diagram illustrating a configuration example of a communication device including amplifier circuits;

FIG. 2 is a circuit diagram illustrating an amplifier circuit according to a comparative example;

FIG. 3 is a circuit diagram illustrating an amplifier circuit according to a first embodiment;

FIG. 4 is a diagram illustrating a configuration example of a switch in FIG. 3;

FIG. 5 is a diagram illustrating an example of a change in a control signal for each switch in FIG. 3;

FIG. 6 is a diagram illustrating an example of simulation results for the case where an amplifier circuit transitions from an operating state where the amplifier circuit performs amplification operation to a standby state;

FIG. 7 is a diagram illustrating an example of a signal that becomes high level only for a certain period of time;

FIG. 8 is a diagram illustrating the simulation results of the drain-gate voltage of each FET when the amplifier circuit transitions from an operating state to a standby state;

FIG. 9 is a diagram illustrating the simulation results of the drain-gate voltage of each FET when the amplifier circuit transitions from an operating state to a standby state;

FIG. 10 is a diagram illustrating the simulation results of the drain-gate voltage of each FET when the amplifier circuit transitions from an operating state to a standby state;

FIG. 11 is a diagram illustrating the simulation results of the drain-gate voltage of each FET when the amplifier circuit transitions from an operating state to a standby state;

FIG. 12 is a diagram illustrating the simulation results of the drain-gate voltage of each FET when the amplifier circuit transitions from an operating state to a standby state;

FIG. 13 is a diagram illustrating an operation example of the amplifier circuit illustrated in FIG. 3;

FIG. 14 is a diagram illustrating an operation example of the amplifier circuit illustrated in FIG. 3;

FIG. 15 is a diagram illustrating an operation example of the amplifier circuit illustrated in FIG. 3;

FIG. 16 is a circuit diagram illustrating an amplifier circuit according to a second embodiment;

FIG. 17 is a diagram illustrating simulation results for the case where diodes in FIG. 16 are not connected;

FIG. 18 is a diagram illustrating the operation in the case where diodes are connected as in FIG. 16;

FIG. 19 is a circuit diagram illustrating an amplifier circuit according to a third embodiment; and

FIG. 20 is a circuit diagram illustrating an amplifier circuit according to a fourth embodiment.

### DETAILED DESCRIPTION

Hereinafter, embodiments of the present disclosure will be described in detail based on the drawings. In the description of each of the following embodiments, configuration portions identical or equivalent to other embodiments are given the same reference numerals, and descriptions thereof are abbreviated or omitted. The present disclosure is not limited by each embodiment. Moreover, the constituent elements of each embodiment may include those that are replaceable and easily substitutable by one skilled in the art, or those that are substantially identical. Note that the configurations described below can be combined as appropriate. In addition, the configurations can be omitted, replaced, or changed within the scope that does not deviate from the gist of the disclosure.

### Communication Device

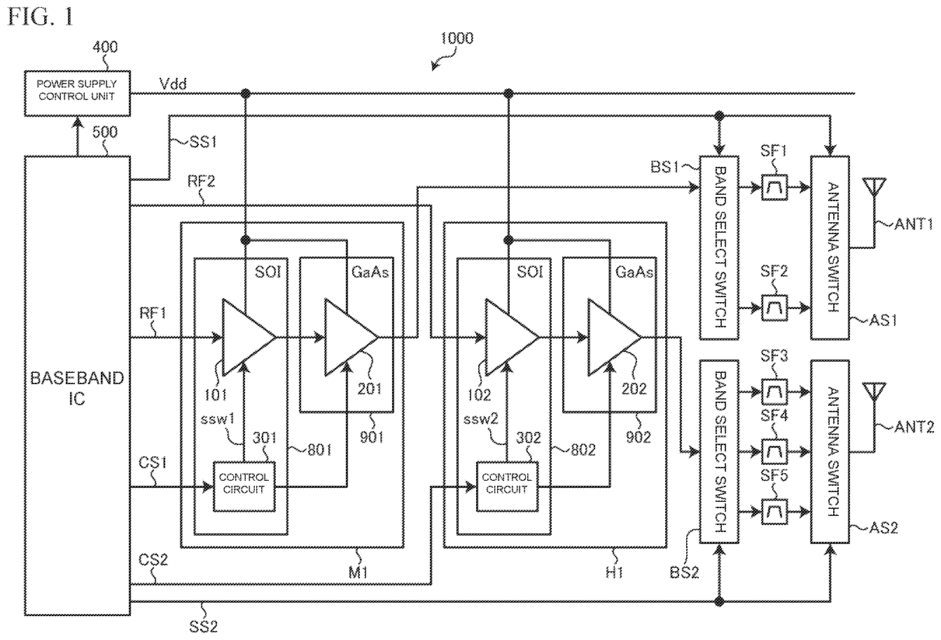

First, a communication device including amplifier circuits will be described. FIG. 1 is a diagram illustrating a configuration example of a communication device including amplifier circuits. In FIG. 1, a communication device 1000 includes a power amplifier circuit M1, a power amplifier circuit H1, band select switches BS1 and BS2, filters SF1 to SF5, antenna switches AS1 and AS2, antennas ANT1 and ANT2, a power supply control unit 400, and a baseband IC (Integrated Circuit) 500.

Each of the power amplifier circuit M1 and the power amplifier circuit H1 is a PA (Power Amplifier) module and have a function as a power amplifier circuit. When one of the power amplifier circuit M1 and the power amplifier circuit H1 is performing amplification operation, the other is in a standby state in which amplification operation is not performed. That is, the power amplifier circuit M1 and the power amplifier circuit H1 selectively enter an operating state, and enter a standby state when not in an operating state. Of the power amplifier circuit M1 and the power amplifier circuit H1, one that is in an amplification operating state operates in one of the following modes: High Power Mode (HPM), Middle Power Mode (MPM), and Low Power Mode (LPM).

The power amplifier circuit M1 includes amplifier circuits 101 and 201 and a control circuit 301. The amplifier circuit 101 is an amplifier circuit at a preceding stage, namely, a driver stage. The amplifier circuit 201 is an amplifier circuit at a subsequent stage, namely, a power stage. The amplifier circuit 201 at the power stage is configured by, for example, a bipolar transistor. The control circuit 301 is a circuit that outputs control signals for controlling the amplifier circuits 101 and 201. For example, the control circuit 301 inputs a gate bias control signal ssw1 to the amplifier circuit 101. The control circuit 301 inputs a bias current to the amplifier circuit 201. The amplifier circuit 101 and the control circuit 301 are realized by, for example, an SOI (Silicon on Insulator) substrate 801. The amplifier circuit 201 is realized by, for example, a GaAs substrate 901.

The power amplifier circuit H1 includes amplifier circuits 102 and 202 and a control circuit 302. The amplifier circuit 102 is an amplifier circuit at a preceding stage, namely, a driver stage. The amplifier circuit 202 is an amplifier circuit at a subsequent stage, namely, a power stage. The amplifier circuit 202 at the power stage is configured by, for example, a bipolar transistor. The control circuit 302 is a circuit that outputs control signals for controlling the amplifier circuits 102 and 202. For example, the control circuit 302 inputs a gate bias control signal ssw2 to the amplifier circuit 102. The control circuit 302 inputs a bias current to the amplifier circuit 202. In this example, the amplifier circuit 102 and the control circuit 302 are realized by, for example, an SOI substrate 802. The amplifier circuit 202 is realized by, for example, a GaAs substrate 902.

The band select switch BS1 is a switch that selects a frequency band based on a band select control signal SS1. The band select switch BS2 is a switch that selects a frequency band based on a band select control signal SS2.

The filters SF1 to SF5 are, for example, SAW (Surface Acoustic Wave) filters. Each of the filters SF1 and SF2 extracts signals in a required frequency band from the output of the band select switch BS1. The filters SF3 to SF5 each extract signals in a required frequency band from the output of the band select switch BS2.

The antenna switch AS1 selects the output of the filter SF1 or the output of the SF2 based on the band select control signal SS1. The antenna switch AS2 selects the output of the filter SF3, the output of the filter SF4, or the output of the filter SF5 based on the band select control signal SS2. The antenna ANT1 emits a signal selected by the antenna switch AS1 as an electromagnetic wave. The antenna ANT2 emits a signal selected by the antenna switch AS2 as an electromagnetic wave.

The power supply control unit 400 is a power supply control module that outputs a power supply Vdd. The power supply Vdd is input to the power amplifier circuit M1 and the power amplifier circuit H1. The power supply control unit 400 includes, for example, a DC-DC (Direct Current-Direct Current) converter that converts a DC voltage level.

The baseband IC 500 transmits RF signals to the power amplifier circuit M1 and the power amplifier circuit H1. The baseband IC 500 also sends control signals CS1 and CS2 and the band select control signals SS1 and SS2 to the respective parts in the communication device 1000 in accordance with the to-be-output frequency band. The baseband IC 500 sends control signals to the band select switches BS1 and BS2 and the antenna switches AS1 and AS2.

### Operation

The baseband IC 500 controls each part of the communication device 1000 to ensure that the signal passes through a desired path, and transmits an RF signal. The RF signal is input to one of the power amplifier circuit M1 and the power amplifier circuit H1 that is in an amplification operating state. For example, when the power amplifier circuit H1 is in an amplification operating state, an RF signal RF2 is input to the power amplifier circuit H1. The power amplifier circuit H1 performs amplification operation on the RF signal RF2 using the amplifier circuits 102 and 202. The amplified signal is output from the antenna ANT2 by way of the band select switch BS2, the filter SF3, SR4, or SF5, and the antenna switch AS2.

Moreover, when the power amplifier circuit M1 is in an amplification operating state, an RF signal RF1 is input to the power amplifier circuit M1. The power amplifier circuit M1 performs amplification operation on the RF signal RF1 using the amplifier circuits 101 and 201. The amplified signal is output from the antenna ANT1 by way of the band select switch BS1, the filter SF1 or SF2, and the antenna switch AS1.

The voltage value of the power supply Vdd output by the power supply control unit 400 is controlled according to the output power of the power amplifier circuit M1 or the power amplifier circuit H1 that is in an operating state. Therefore, the voltage value of the power supply Vdd fluctuates. For example, the voltage value of the power supply Vdd fluctuates in the case of performing average power tracking (APT) or envelope tracking (ET).

The control circuit 301 is a circuit that outputs control signals for controlling the amplifier circuits 101 and 201. In this example, it is assumed that the power amplifier circuit M1 is in a standby state and the power amplifier circuit H1 is in an operating state. The RF signal RF1 is not input to the power amplifier circuit M1, which is in a standby state. The power amplifier circuit M1 and the power amplifier circuit H1 have the same configuration and function. For this reason, the following mainly describes the power amplifier circuit M1, and the description of the power amplifier circuit H1 is omitted as appropriate.

A comparative example will be described below to facilitate the understanding of the embodiments.

### Comparative Example

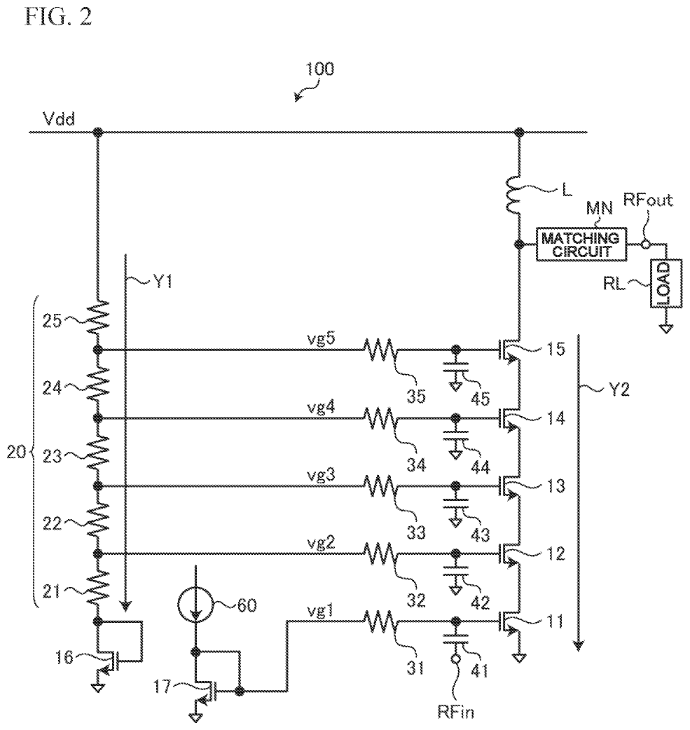

FIG. 2 is a circuit diagram illustrating an amplifier circuit 100 according to the comparative example. The amplifier circuit 100 corresponds to the amplifier circuit 101 or 102 at the driver stage in FIG. 1. In FIG. 2, the amplifier circuit 100 of this example includes a plurality of field effect transistors, namely, FETs (hereinafter referred to as FETs). The amplifier circuit 100 includes FETs 11, 12, 13, 14, and 15, resistors 21, 22, 23, 24, and 25, resistors 31, 32, 33, 34, and 35, capacitors 41, 42, 43, 44, and 45, and an FET 16.

The FETs 11, 12, 13, 14, and 15 are provided between a reference potential and the power supply Vdd. The FETs 11, 12, 13, 14, and 15 are connected in a vertical stack by having their adjacent drains and sources connected. That is, the drain of the FET 11 is connected to the reference potential, and the source of the FET 11 is connected to the drain of the FET 12. The source of the FET 12 is connected to the drain of the FET 13. The source of the FET 13 is connected to the drain of the FET 14. The source of the FET 14 is connected to the drain of the FET 15. The source of the FET 15 is connected to the power supply Vdd with a choke coil L interposed therebetween. In this paper, the FET 11 may be referred to as a first FET, the FET 12 as a second FET, the FET 13 as a third FET, the FET 14 as a fourth FET, and the FET 15 as a fifth FET, respectively. The reference potential is, for example, a ground potential. The same is true in the following description.

The power supply Vdd is a variable power supply, and its voltage value fluctuates, rather than being a fixed value. An output terminal RFout is connected between the choke coil L and the FET 15 with a matching circuit MN interposed therebetween. A load RL is connected to the output terminal RFout. Note that, when viewed from the drain of the FET 15, a portion including the choke coil L and the matching circuit MN, along with the load RL, appears as a load impedance. The output terminal RFout is connected to the power supply Vdd with the choke coil L interposed therebetween. The output terminal RFout is provided between the FET 12, which is the second FET, and the load RL.

The resistor 31 and the capacitor 41 are provided corresponding to the FET 11. A first end of the resistor 31 and a first end of the capacitor 41 are respectively connected to the gate of the FET 11. A second end of the capacitor 41 is connected to an input terminal RFin. A signal to be amplified is input to the input terminal RFin.

The resistor 32 and the capacitor 42 are provided corresponding to the FET 12. A first end of the resistor 32 and a first end of the capacitor 42 are respectively connected to the gate of the FET 12. A second end of the capacitor 42 is connected to the reference potential.

The resistor 33 and the capacitor 43 are provided corresponding to the FET 13. A first end of the resistor 33 and a first end of the capacitor 43 are respectively connected to the gate of the FET 13. A second end of the capacitor 43 is connected to the reference potential.

The resistor 34 and the capacitor 44 are provided corresponding to the FET 14. A first end of the resistor 34 and a first end of the capacitor 44 are respectively connected to the gate of the FET 14. A second end of the capacitor 44 is connected to the reference potential.

The resistor 35 and the capacitor 45 are provided corresponding to the FET 15. A first end of the resistor 35 and a first end of the capacitor 45 are respectively connected to the gate of the FET 15. A second end of the capacitor 45 is connected to the reference potential.

The FET 16 has its drain and gate connected, which is a so-called diode connection. The FET 16 is provided between the resistor 21 and the reference potential.

The resistance values of the resistors 31, 32, 33, 34, and 35 are, for example, several [kΩ]. Also, the capacitance values of the capacitors 41, 42, 43, 44, and 45 range from, for example, several tens of [pF] to several [pF].

The resistors 21, 22, 23, 24, and 25 are ladder resistors connected in series between the power supply Vdd and the reference potential. The resistors 21, 22, 23, 24, and 25 become a voltage divider resistor circuit 20. The voltage divider resistor circuit 20 divides the potential difference between the power supply Vdd and the reference potential, and generates a bias to be applied to each gate of the FET 12 to the FET 15. By realizing the resistors 21, 22, 23, 24, and 25 with identical ladder resistors, it is possible to prevent reversal of gate bias in each stage due to mismatches between resistors. Here, “identical ladder resistors” refer to ladder resistors that are identical in terms of manufacturing process and materials.

A first end of the resistor 21 is connected to the drain and gate of the FET 16. The first end of the resistor 21 is connected to the reference potential with a diode by the FET 16 interposed therebetween. The FET 16 is connected to the reference potential side of the voltage divider resistor circuit 20. Therefore, the FET 16 is provided between the voltage divider resistor circuit 20 and the reference potential.

In the voltage divider resistor circuit 20, the resistor 21 and the resistor 22 are connected in series. The connection point between the resistor 21 and the resistor 22 is connected to the second end of the resistor 32. The voltage at the connection point between the resistor 21 and the resistor 22 is applied as a bias vg2 to the gate of the FET 12. The resistor 22 and the resistor 23 are connected in series. The connection point between the resistor 22 and the resistor 23 is connected to the second end of the resistor 33. The voltage at the connection point between the resistor 22 and the resistor 23 is applied as a bias vg3 to the gate of the FET 13. The resistor 23 and the resistor 24 are connected in series. The connection point between the resistor 23 and the resistor 24 is connected to the second end of the resistor 34. The voltage at the connection point between the resistor 23 and the resistor 24 is applied as a bias vg4 to the gate of the FET 14. The resistor 24 and the resistor 25 are connected in series. The connection point between the resistor 24 and the resistor 25 is connected to the second end of the resistor 35. The voltage at the connection point between the resistor 24 and the resistor 25 is applied as a bias vg5 to the gate of the FET 15.

Also, in FIG. 2, the amplifier circuit 100 of this example includes an FET 17 and a constant current source 60. The constant current source 60 outputs a constant current. The FET 17 is connected to the output side of the constant current source 60. The FET 17 has its drain and gate connected, which is a so-called diode connection. A second end of the resistor 31 is connected to the FET 17. The FET 17 is a replica transistor that forms a current mirror circuit along with the first FET 11. The current mirror circuit formed of the FET 11 and the FET 17 causes a current proportional to the constant current output from the constant current source 60 to flow between the drain and the source of the FET 11.

### Operation of Comparative Example

In the amplifier circuit 100 illustrated in FIG. 2, each gate of the FET 12 to the FET 15 is applied with a bias (that is, a gate a bias) generated by the resistor voltage division of the voltage divider resistor circuit 20. The amplifier circuit 100 amplifies a radio frequency signal input to the input terminal RFin. The amplifier circuit 100 outputs the amplified signal from the output terminal RFout.

Here, there are cases in which one of the power amplifier circuit M1 and the power amplifier circuit H1 illustrated in FIG. 1 is performing amplification operation, while the other power amplifier circuit is not performing amplification operation. Since the power amplifier circuit M1 and the power amplifier circuit H1 share the power supply Vdd, the power supply Vdd is also supplied to the power amplifier circuit that is not performing power amplification.

In the case where the amplifier circuit 100 illustrated in FIG. 2 is not performing amplification operation, the amplifier circuit 100 is in a standby state. Even in a standby state, the amplifier circuit 100 is supplied with the power supply Vdd. Therefore, even in a standby state, leakage current flows through the voltage divider resistor circuit 20, as indicated by arrow Y1. That is, leakage current flows from the power supply Vdd through the voltage divider resistor circuit 20 towards the FET 16. Also, as indicated by arrow Y2, leakage current flows from the power supply Vdd through the choke coil L, from the FET 15 towards the FET 11.

That is, when the amplifier circuit 100 is connected to a power supply line common to another amplifier circuit with a different operating timing, the voltage of the power supply Vdd will be applied to the amplifier circuit 100 even if the amplifier circuit 100 is not performing power amplification (that is, when in a standby state). At this time, leakage current may be generated by the power supply Vdd. For an amplifier circuit in a standby state, there is a challenge in reducing the leakage current due to the power supply Vdd.

### First Embodiment

The embodiments will now be described.

### Configuration

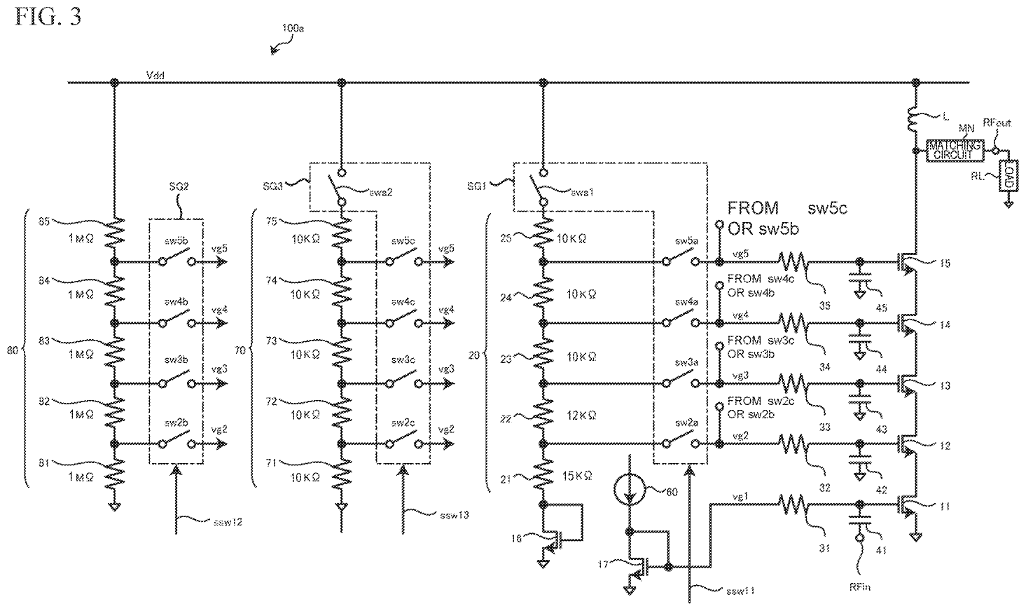

FIG. 3 is a circuit diagram illustrating an amplifier circuit 100a according to a first embodiment. The amplifier circuit 100a corresponds to the amplifier circuit 101 or 102 at the driver stage in FIG. 1. In FIG. 3, the amplifier circuit 100a is a configuration in which the amplifier circuit 100 described with reference to FIG. 2 is supplemented with a voltage divider resistor circuit 80, a switch swa1, a switch swa2, switches sw2a, sw3a, sw4a and sw5a, switches sw2b, sw3b, sw4b and sw5b, and switches sw2c, sw3c, sw4c and sw5c. In this paper, the switch swa1 may be referred to as a first switch element, the switch swa2 as a second switch element, the switches sw2b, sw3b, sw4b, and sw5b as third switch elements, the switches sw2a, sw3a, sw4a, and sw5a as fourth switch elements, and the switches sw2c, sw3c, sw4c, and sw5c as fifth switch elements. Also, in this paper, the voltage divider resistor circuit 20 may be referred to as a first voltage divider resistor circuit, the voltage divider resistor circuit 80 as a second voltage divider resistor circuit, and a voltage divider resistor circuit 70 as a third voltage divider resistor circuit.

The switches sw2a, sw3a, sw4a and sw5a, which are the fourth switch elements, are provided between the voltage divider resistor circuit 20 and the FET 12 to the FET 15. The voltage divider resistor circuit 20 supplies biases to the FET 12 to the FET 15 by way of the switches sw2a, sw3a, sw4a, and sw5a.

The switches sw2b, sw3b, sw4b, and sw5b, which are the third switch elements, are provided between the voltage divider resistor circuit 80 and the FET 12 to the FET 15. The voltage divider resistor circuit 80 supplies biases to the FET 12 to the FET 15 by way of the switches sw2b, sw3b, sw4b, and sw5b.

The switches sw2c, sw3c, sw4c, and sw5c, which are the fifth switch elements, are provided between the voltage divider resistor circuit 70 and the FET 12 to the FET 15. The voltage divider resistor circuit 70 supplies biases to the FET 12 to the FET 15 by way of the switches sw2c, sw3c, sw4c, and sw5c.

The voltage divider resistor circuit 80, which is the second voltage divider resistor circuit, is provided between the power supply Vdd and the reference potential. The voltage divider resistor circuit 80 includes resistors 81, 82, 83, 84 and 85. The voltage divider resistor circuit 80 divides the potential difference between the power supply Vdd and the reference potential, and generates biases to be applied to the gates of the FET 12 to the FET 15.

The voltage divider resistor circuit 70, which is the third voltage divider resistor circuit, is provided between the switch swa2 and the reference potential. The voltage divider resistor circuit 70 is connected to the power supply Vdd with the switch swa2 interposed therebetween. The voltage divider resistor circuit 70 includes resistors 71, 72, 73, 74 and 75. The voltage divider resistor circuit 70 divides the potential difference between the power supply Vdd and the reference potential when the switch swa2 is in the on state, and generates biases to be applied to the gates of the FET 12 to the FET 15.

The resistance value of each of the resistors 81, 82, 83, 84, and 85 included in the voltage divider resistor circuit 80 is greater than the resistance value of each of the resistors 21, 22, 23, 24, and 25 included in the voltage divider resistor circuit 20. The resistance value of each of the resistors 71, 72, 73, 74, and 75 included in the voltage divider resistor circuit 70 is less than the resistance value of each of the resistors 81, 82, 83, 84, and 85 included in the voltage divider resistor circuit 80. For example, in the voltage divider resistor circuit 20, the resistor 21 is 15 [kΩ], the resistor 22 is 12 [kΩ], and the resistor 23, the resistor 24, and the resistor 25 are 10 [kΩ]. Also, for example, in the voltage divider resistor circuit 80, the resistors 81 to 85 are all 1 [MΩ]. In this example, the resistance values of the resistors in the voltage divider resistor circuit 70 are all 10 [kΩ]. The voltage division ratio of the resistors in the voltage divider resistor circuit 70 is identical to the voltage division ratio of the resistors in the voltage divider resistor circuit 80. Having an identical voltage division ratio refers to the case where the voltage division ratios of the voltage divider resistor circuit 70 and the voltage divider resistor circuit 80 match each other. The fact that the voltage division ratios of the voltage divider resistor circuit 70 and the voltage divider resistor circuit 80 match each other includes, in addition to the aspect in which the voltage division ratios of the voltage divider resistor circuit 70 and the voltage divider resistor circuit 80 exactly match each other, the aspect in which there is a difference between the voltage division ratios to the extent that turning on/off of the electrical connection between the voltage divider resistor circuit 70 and the power supply Vdd does not affect biases to be applied to the gates of the FET 12 to the FET 15.

The switch swa1 is provided between the voltage divider resistor circuit 20 and the power supply Vdd. The switch swa1 is a switch element for turning on/off the electrical connection between the power supply Vdd and the voltage divider resistor circuit 20. The switch swa1 turns on when the amplification operation by the amplifier circuit 100a is performed. In addition, the switch swa1 turns off when the amplification operation by the amplifier circuit 100a is not performed. That is, the switch swa1 turns on when the amplification operation by the FET 11 to the FET 15 is performed. In addition, the switch swa1 turns off when the amplification operation by the FET 11 to the FET 15 is not performed (that is, when in a standby state).

The switch swa1, and the switches sw2a, sw3a, sw4a and sw5a simultaneously turn on or off. Each of these switches turns on or off in response to a control signal ssw11. Each of these switches turns on when the control signal ssw11 is at high level (high) and turns off when the control signal ssw11 is at low level (low). Hereinafter, the switch swa1, and the switches sw2a, sw3a, sw4a, and sw5a may be referred to as a switch group SG1. The control signal ssw11 is included in the gate bias control signal ssw1 (see FIG. 1) output from the control circuit 301. The control signal ssw11 is generated by the control circuit in the PA module based on a control signal sent from the baseband IC 500 (see FIG. 1).

The switches sw2b, sw3b, sw4b and sw5b simultaneously turn on or off. Each of these switches turns on or off in response to a control signal ssw12. Each of these switches turns on when the control signal ssw12 is at high level (high) and turns off when the control signal ssw12 is at low level (low). Hereinafter, the switches sw2b, sw3b, sw4b and sw5b may be referred to as a switch group SG2. The control signal ssw12 is included in the gate bias control signal ssw1 (see FIG. 1) output from the control circuit 301. The control signal ssw12 is generated by the control circuit in the PA module based on a control signal sent from the baseband IC 500 (see FIG. 1).

The switch swa2, and the switches sw2c, sw3c, sw4c, and sw5c simultaneously turn on or off. Each of these switches turns on or off in response to a control signal ssw13. Each of these switches turns on when the control signal ssw13 is at high level (high) and turns off when the control signal ssw13 is at low level (low). Hereinafter, the switch swa2, and the switches sw2c, sw3c, sw4c, and sw5c may be referred to as a switch group SG3. The control signal ssw13 is included in the gate bias control signal ssw1 (see FIG. 1) output from the control circuit 301. The control signal ssw13 is generated by the control circuit in the PA module based on a control signal sent from the baseband IC 500 (see FIG. 1).

The switch group SG1 and the switch group SG2 selectively turn on or off. That is, when the switch group SG1 is in the on state, the switch group SG2 is in the off state. When the switch group SG1 is in the off state, the switch group SG2 is in the on state. In this way, the switch group SG1 and the switch group SG2 turn on and off independently. The switch group SG1 turns on when in an operating state in which amplification operation is performed, and turns off when in a standby state. The switch group SG2 turns off when in an operating state in which amplification operation is performed, and turns on when in a standby state. The switch group SG3 turns on for a short period of time (such as about a few hundred ns to a few μs) after switching from an operating state in which amplification operation is performed to a standby state, and turns off at other timings.

The third switch elements sw2b to sw5b turn off when the first switch element swa1 turns on. The third switch elements sw2b to sw5b turn on when the first switch element swa1 turns off.

The fourth switch elements sw2a to sw5a turn on when the first switch element swa1 turns on. The fourth switch elements sw2a to sw5a turn off when the first switch element swa1 turns off.

The fifth switch elements sw2c to sw5c turn on when the second switch element swa2 turns on. The fifth switch elements sw2c to sw5c turn off when the second switch element swa2 turns off.

Therefore, when the switches sw2a, sw3a, sw4a and sw5a, which are the fourth switch elements, are in the on state, the switches sw2b, sw3b, sw4b and sw5b, which are the third switch elements, are in the off state. When the switches sw2a, sw3a, sw4a and sw5a, which are the fourth switch elements, are in the off state, the switches sw2b, sw3b, sw4b and sw5b, which are the third switch elements, are in the on state.

The switches sw2a, sw3a, sw4a and sw5a, which are the fourth switch elements, and the switches sw2b, sw3b, sw4b and sw5b, which are the third switch elements, selectively turn on or off. That is, when the switches sw2a, sw3a, sw4a and sw5a, which are the fourth switch elements, are in the on state, the switches sw2b, sw3b, sw4b and sw5b, which are the third switch elements, are in the off state. When the switches sw2a, sw3a, sw4a and sw5a, which are the fourth switch elements, are in the off state, the switches sw2b, sw3b, sw4b and sw5b, which are the third switch elements, are in the on state. In this way, the switches sw2a, sw3a, sw4a and sw5a and the switches sw2b, sw3b, sw4b and sw5b turn on/off independently.

In the switch group SG1, the switch swa1 and the switches sw2a, sw3a, sw4a and sw5a turn on/off in conjunction. That is, the switch swa1 and the switches sw2a, sw3a, sw4a and sw5a simultaneously turn on or off. That is, when the switch swa1 is in the on state, the switches sw2a, sw3a, sw4a, and sw5a are in the on state. When the switch swa1 is in the off state, the switches sw2a, sw3a, sw4a, and sw5a are in the off state. In short, the switch swa1, which is the first switch element, turns on when the switches sw2a, sw3a, sw4a and sw5a, which are the fourth switch elements, turn on. In addition, the switch swa1 turns off when the switches sw2a, sw3a, sw4a and sw5a turn off. Furthermore, the switches sw2a, sw3a, sw4a and sw5a, which are the fourth switch elements, turn off when the switches sw2b, sw3b, sw4b and sw5b, which are the third switch elements, turn on. Also, the switches sw2a, sw3a, sw4a and sw5a turn on when the switches sw2b, sw3b, sw4b and sw5b turn off.

### Configuration Example of Switches

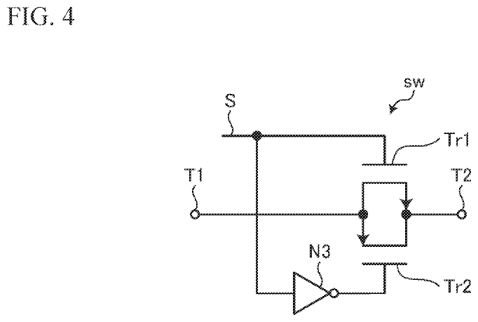

FIG. 4 is a diagram illustrating a configuration example of a switch in FIG. 3. A switch sw illustrated in FIG. 4 indicates a configuration example of each switch in FIG. 3. In FIG. 4, the switch sw includes an N-type MOS transistor Tr1, a P-type MOS transistor Tr2, an inverter (NOT circuit) N3, and terminals T1 and T2. The inverter N3 inverts a control signal S.

The N-type MOS transistor Tr1 and the P-type MOS transistor Tr2 have their sources connected together, and their drains connected together. Signals inverted from each other by the inverter N3 are applied to the gate of the N-type MOS transistor Tr1 and the gate of the P-type MOS transistor Tr2. Therefore, the N-type MOS transistor Tr1 and the P-type MOS transistor Tr2 simultaneously turn on and simultaneously turn off. Thus, based on the control signal S, the switch sw turns on, allowing a signal to pass between the terminal T1 and the terminal T2, or turns off, not allowing the signal to pass between the terminal T1 and the terminal T2. Therefore, the switch sw can turn on/off the electrical connection between the terminal T1 and the terminal T2. In each subsequent embodiment, the configuration of each switch used is the same as or similar to that illustrated in FIG. 4.

### Operation

Referring back to FIG. 3, in the case of performing amplification operation using the amplifier circuit 100a, the switch swa1 is turned on. Accordingly, each gate of the FET 12 to the FET 15 is applied with a bias (i.e., a gate bias) generated by the resistor voltage division of the voltage divider resistor circuit 20. The amplifier circuit 100a amplifies a radio frequency signal input to the input terminal RFin. The amplifier circuit 100a outputs the amplified signal from the output terminal RFout.

When in a standby state in which amplification operation is not performed by the amplifier circuit 100a illustrated in FIG. 3, the switch swa1 is turned off. Accordingly, the voltage due to the power supply Vdd is not applied to the voltage divider resistor circuit 20. However, it is suitable to apply biases in the amplifier circuit 100a for countermeasures against breakdown voltage. Therefore, to achieve a minimum leakage current, biases are generated by the voltage divider resistor circuit 80 with resistors having large resistance values.

### Operation

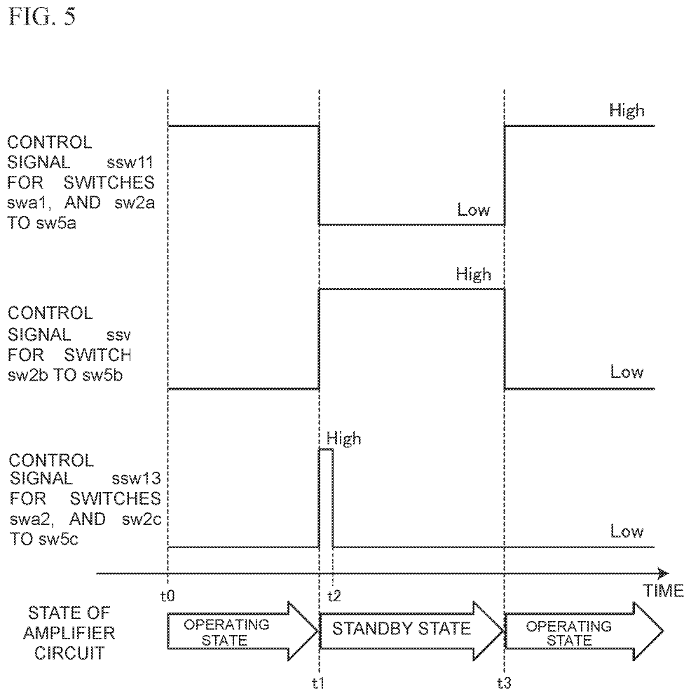

FIG. 5 is a diagram illustrating an example of a change in a control signal for each switch in FIG. 3. In FIG. 5, the horizontal axis indicates the passage of time. FIG. 5 illustrates the timing of a change in the control signals ssw11, ssw12, and ssw13 in FIG. 3 and the state of the amplifier circuit. In FIG. 5, the control signal ssw11 is a control signal for the switch group SG1. At time to, when the control signal ssw11 is at high level, each switch included in the switch group SG1 turns on, and the amplifier circuit 100a enters an operating state in which amplification operation is performed. At this time, the control signal ssw12 is at low level, and each switch included in the switch group SG2 is in the off state. In addition, the control signal ssw13 is at low level, and each switch included in the switch group SG3 is in the off state.

Next, when the amplifier circuit 100a transitions from an operating state in which amplification operation is performed to a standby state in which amplification operation is not performed, the following operation is performed. That is, at time t1, the control signal ssw11 becomes low level, and the control signal ssw12 becomes high level. Each switch included in the switch group SG1 turns off, and each switch included in the switch group SG2 turns on. Accordingly, the amplifier circuit 100a transitions to a standby state.

In addition, for a short period of time from time t1 to time t2, the control signal ssw13 becomes high level to turn off the switch swa1, which is the first switch element, and electrically disconnect the voltage divider resistor circuit 20 and the power supply Vdd. With the control signal ssw13 becoming high level, each switch, such as the second switch element swa2, included in the switch group SG3 turns on. Accordingly, the voltage divider resistor circuit 70 and the power supply Vdd are electrically connected for a short period of time from time t1 to time t2.

After a short period of time from time t1 to time t2, that is, after time t2 at which a certain period of time has elapsed, the control signal ssw13 becomes low level. Accordingly, the second switch element swa2 turns off, and the voltage divider resistor circuit 70 and the power supply Vdd are electrically disconnected. In other words, each switch, such as the second switch element swa2, included in the switch group SG3 turns off at time t2 at which a certain period of time has elapsed since time t1 at which the amplifier circuit 100a transitions to a standby state. Accordingly, the voltage divider resistor circuit 70 and the power supply Vdd are electrically disconnected. Note that the certain period of time from time t1 to time t2 is, for example, about several hundred ns to several μs.

From time t2 to time t3, there is no change in the control signals ssw11, ssw12, and ssw13, so the state of each switch is maintained. Therefore, the amplifier circuit 100a is in a standby state.

After that, at time t3, when the control signal ssw11 becomes high level, each switch included in the switch group SG1 turns on, and the amplifier circuit 100a enters an operating state in which amplification operation is performed. At this time, the control signal ssw12 is at low level, and each switch included in the switch group SG2 is in the off state. In addition, the control signal ssw13 is at low level, and each switch included in the switch group SG3 is in the off state.

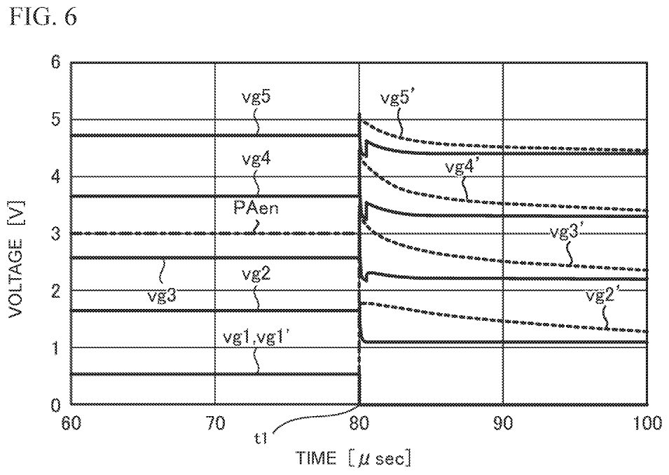

FIG. 6 is a diagram illustrating an example of simulation results for the case where the amplifier circuit transitions from an operating state where the amplifier circuit performs amplification operation to a standby state. FIG. 6 illustrates a change in each of the biases vg1, vg2, vg3, vg4, and vg5 in FIG. 3. In FIG. 6, the vertical axis indicates the voltage [V], and the horizontal axis indicates the time [μsec]. Moreover, in FIG. 6, a dash-dotted line PAen indicates a signal for controlling the operating state of the amplifier circuit. In this example, the circuit is created so that the amplifier circuit enters an operating state when the dash-dotted line PAen is at high level, and the amplifier circuit enters a standby state when the dash-dotted line PAen is at low level.

FIG. 6 illustrates the case in which the amplifier circuit transitions from an operating state to a standby state at time t1. When each switch is controlled as described with reference to FIG. 5, the biases vg1, vg2, vg3, vg4, and vg5 change as indicated by solid lines in FIG. 6. That is, at time t1, the biases vg2, vg3, vg4, and vg5 decrease rapidly because the voltage divider resistor circuit 70 with small resistance values is connected for a certain period of time.

In the meantime, if each switch is not controlled, biases vg2′, vg3′, vg4′, and vg5′ gradually decrease as the amplifier circuit transitions from an operating state to a standby state, as indicated by broken lines in FIG. 6. This is because they are affected by a time constant based on the large resistance values and the capacitance values of the capacitors 42 to 45 of the gates of the FETs 12 to 15. In FIG. 6, because the bias vg1 is not affected by the above-mentioned time constant, the bias vg1 changes in the same way as the bias vg1′ in the case of not controlling each switch.

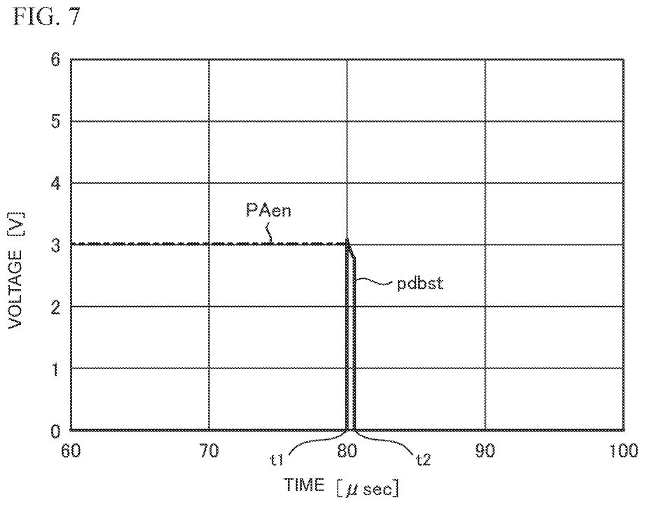

FIG. 7 is a diagram illustrating an example of a signal that becomes high level for a certain period of time. In FIG. 7, the vertical axis indicates the voltage [V], and the horizontal axis indicates the time [μsec]. Moreover, in FIG. 7, like FIG. 6, the dash-dotted line PAen indicates the operating state of the amplifier circuit. As the amplifier circuit transitions from an operating state to a standby state at time t1, a signal pdbst illustrated in FIG. 7 becomes high level for a certain period of time from time t1 to time t2. This certain period of time is, for example, 500 nsec, as described above. As described above, the biases vg2, vg3, vg4, and vg5 can be rapidly reduced only for this certain period of time by connecting the voltage divider resistor circuit 70.

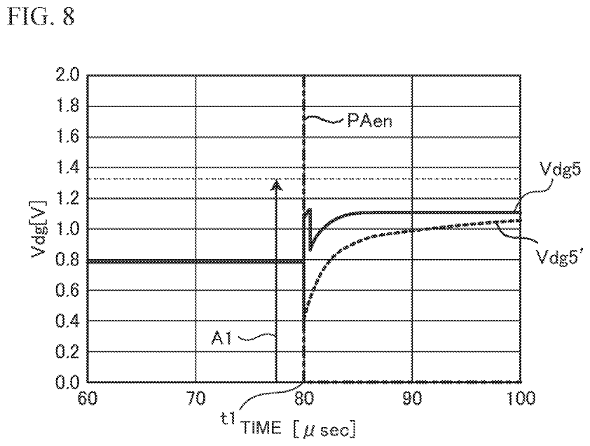

FIGS. 8 to 12 are diagrams illustrating the simulation results of the drain-gate voltage Vdg of each FET when the amplifier circuit 100a transitions from an operating state to a standby state. In FIGS. 8 to 12, like FIG. 6, the dash-dotted line PAen indicates the operating state of the amplifier circuit. At time t1, the amplifier circuit transitions from an operating state to a standby state.

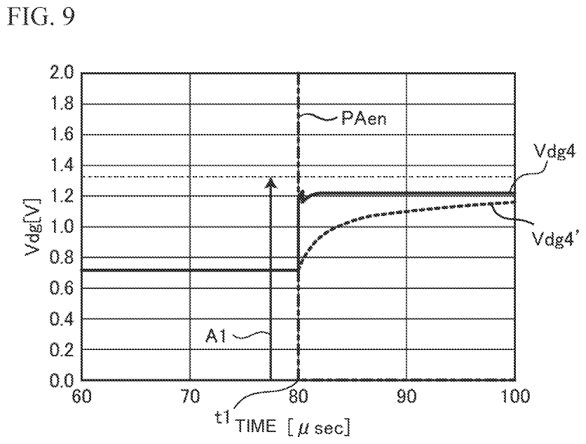

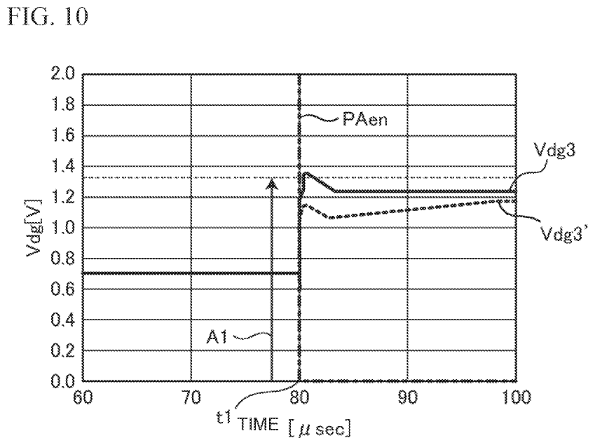

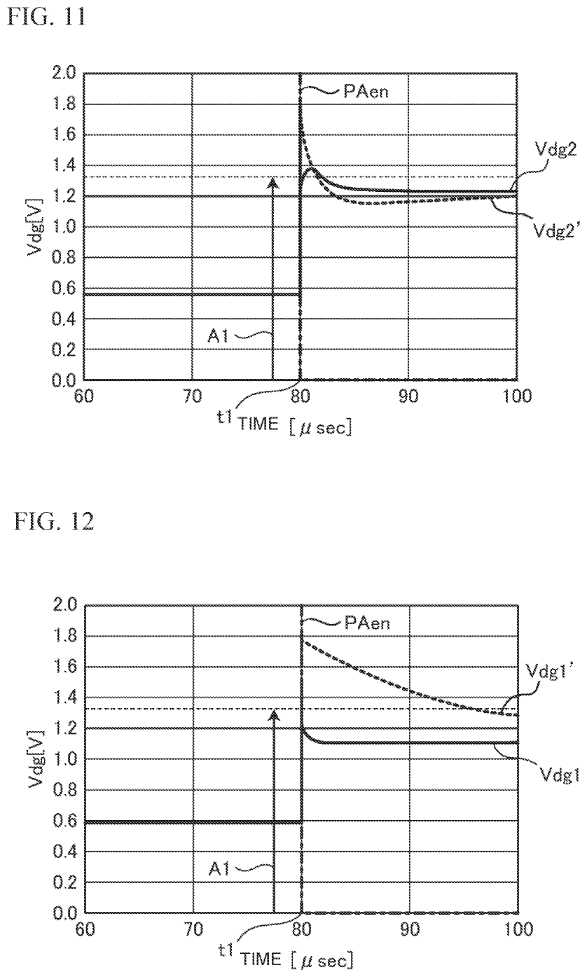

FIG. 8 is a diagram illustrating the simulation results of a drain-gate voltage Vdg5 of the FET 15. FIG. 9 is a diagram illustrating the simulation results of a drain-gate voltage Vdg4 of the FET 14. FIG. 10 is a diagram illustrating the simulation results of a drain-gate voltage Vdg3 of the FET 13. FIG. 11 is a diagram illustrating the simulation results of a drain-gate voltage Vdg2 of the FET 12. FIG. 12 is a diagram illustrating the simulation results of a drain-gate voltage Vdg1 of the FET 11.

As illustrated in FIG. 8, as the amplifier circuit transitions from an operating state to a standby state at time t1, the drain-gate voltage Vdg5 of the FET 15 rises from about 0.8 [V] by about 0.3 [V], as indicated by a solid line in FIG. 8, and then decreases after a certain period of time. After that, the drain-gate voltage Vdg5 rises slowly and stabilizes at about 1.1 [V]. In the meantime, in the case of not controlling each switch as described above, a drain-gate voltage Vdg5′ indicated by a broken line in FIG. 8 decreases by about 0.4 [V], and then rises slowly. The drain-gate voltages Vdg5 and Vdg5′ of the FET 15 both do not exceed an unbroken area A1. That is, they do not exceed the breakdown voltage of the FET 15.

As illustrated in FIG. 9, as the amplifier circuit transitions from an operating state to a standby state at time t1, the drain-gate voltage Vdg4 of the FET 14 rises from about 0.7 [V] by about 0.5 [V], as indicated by a solid line in FIG. 9, and then decreases after a certain period of time. After that, the drain-gate voltage Vdg4 rises slowly and stabilizes at about 1.2 [V]. In the meantime, in the case of not controlling each switch as described above, a drain-gate voltage Vdg4′ indicated by a broken line in FIG. 8 rises slowly from about 0.7 [V]. The drain-gate voltages Vdg4 and Vdg4′ of the FET 14 both do not exceed the unbroken area A1. That is, they do not exceed the breakdown voltage of the FET 14.

As illustrated in FIG. 10, as the amplifier circuit transitions from an operating state to a standby state at time t1, the drain-gate voltage Vdg3 of the FET 13 rises from about 0.7 [V] by about 0.5 [V], as indicated by a solid line in FIG. 10, and then rises further. The drain-gate voltage Vdg3 slightly exceeds the unbroken area A1, but then stabilizes without necessarily exceeding the unbroken area A1. In the meantime, in the case of not controlling each switch as described above, a drain-gate voltage Vdg3′ indicated by a broken line in FIG. 10 rises from about 0.7 [V], but does not exceed the unbroken area A1. The drain-gate voltages Vdg3 and Vdg3′ of the FET 13 both do not exceed the unbroken area A1.

As illustrated in FIG. 11, as the amplifier circuit transitions from an operating state to a standby state at time t1, the drain-gate voltage Vdg2 of the FET 12 rises from about 0.5 [V] to about 1.8 [V], as indicated by a solid line in FIG. 11, and then decreases. The drain-gate voltage Vdg2 may slightly exceed the unbroken area A1, but then stabilizes without necessarily exceeding the unbroken area A1. In the meantime, in the case of not controlling each switch as described above, a drain-gate voltage Vdg2′ indicated by a broken line in FIG. 11 rises slowly from about 0.5 [V] to about 1.6 [V], and then decreases. The drain-gate voltage Vdg2′ may slightly exceed the unbroken area A1, but then stabilizes without necessarily exceeding the unbroken area A1.

As illustrated in FIG. 12, as the amplifier circuit transitions from an operating state to a standby state at time t1, the drain-gate voltage Vdg1 of the FET 11 rises from about 0.6 [V] to about 1.8 [V], as indicated by a solid line in FIG. 12, and then decreases. The drain-gate voltage Vdg2 may slightly exceed the unbroken area A1, but then stabilizes without necessarily exceeding the unbroken area A1. In the meantime, in the case of not controlling each switch as described above, a drain-gate voltage Vdg1′ indicated by a broken line in FIG. 12 rises from about 0.6 [V] to about 1.8 [V], and then decreases slowly. The drain-gate voltage Vdg1′ exceeds the unbroken area A1 for a long period of time.

As indicated by broken lines in FIGS. 8 to 12, in the case of not controlling each switch as described above, the drain-gate voltage Vdg5 of the FET 15 and the drain-gate voltage Vdg4 of the FET 14 decrease, and consequently the potential difference of the drain-gate voltage Vdg1 of the FET 11 increases. As indicated by solid lines in FIGS. 8 to 12, by controlling each switch as described above, the drain-gate voltage Vdg of each stage of the FETs 11 to 15 becomes uniform, and after the drain-gate voltages Vdg stabilize, no stage exceeds the unbroken area A1. That is, each stage of the FETs 11 to 15 does not exceed the breakdown voltage of the FETs.

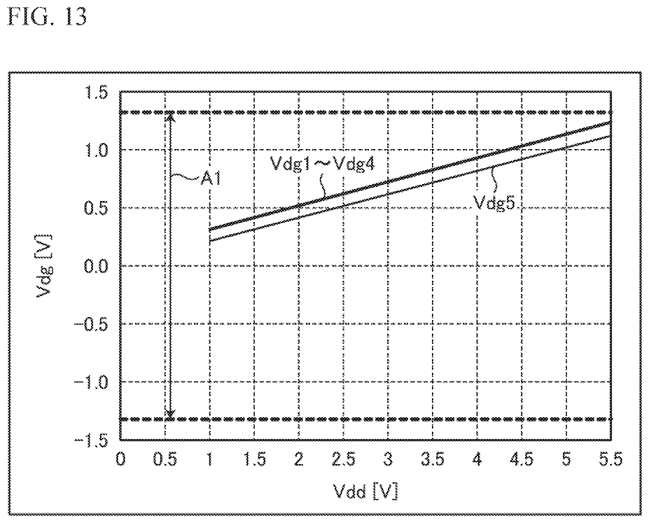

FIGS. 13, 14 and 15 are diagrams illustrating operation examples of the amplifier circuit 100a illustrated in FIG. 3. FIG. 13 is a diagram illustrating the simulation results of the potential difference between the drain and the gate. FIG. 13 is a diagram illustrating the simulation results in a standby state where the amplifier circuit 100a is not performing amplification operation.

In FIG. 13, the horizontal axis is the voltage value [V] of the power supply Vdd, and the vertical axis is the value [V] of the drain-gate voltage Vdg. As illustrated in FIG. 13, as the voltage value of the power supply Vdd rises from 1 [V], the values of the voltages Vdg1 to Vdg4 corresponding to the biases vg1 to vg5 change according to that change. With regard to the voltages Vdg1 to Vdg4, none exceeds the unbroken area A1. Note that the unbroken area A1 is an area where the FET does not reach breakdown as long as it operates within that area.

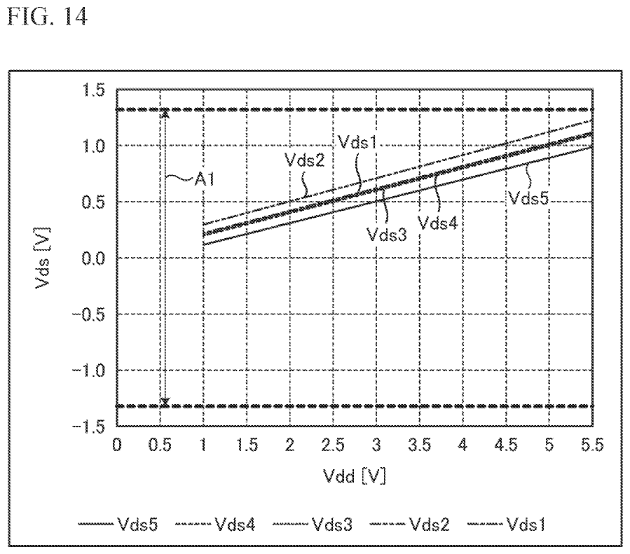

FIG. 14 is a diagram illustrating the simulation results of the drain-source potential difference. FIG. 14 illustrates the simulation results in a standby mode where the amplifier circuit 100a is not performing amplification operation.

In FIG. 14, the horizontal axis is the voltage value [V] of the power supply Vdd, and the vertical axis is the value [V] of the drain-source voltage Vds. As illustrated in FIG. 14, as the voltage value of the power supply Vdd rises from 1 [V], the values of the voltages Vds1 to Vds5 corresponding to the biases vg1 to vg5 change according to that change. With regard to the voltages Vds1 to Vds5, none exceeds the unbroken area A1.

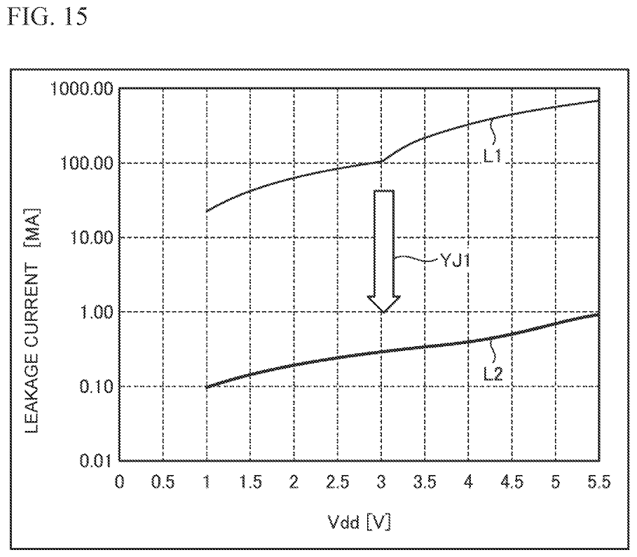

FIG. 15 is a diagram illustrating the simulation results of leakage current. In FIG. 15, the horizontal axis is the voltage value [V] of the power supply Vdd, and the vertical axis is the value [μA] of leakage current. In FIG. 15, a current L1 is a leakage current during the amplification operation of the amplifier circuit 100a. In addition, a leakage current L2 is a leakage current when in a standby mode in which the first voltage divider resistor circuit 20 is disconnected and the second voltage divider resistor circuit 80 is connected. That is, the switch swa1 turns off, and, in conjunction with this, the switches sw2a, sw3a, sw4a and sw5a turn off, while the switches sw2b, sw3b, sw4b and sw5b turn on. This connects the second voltage divider resistor circuit 80, which includes resistors with resistance values greater than the resistors of the first voltage divider resistor circuit 20. By connecting the second voltage divider resistor circuit 80 with large resistance values, the current value of the leakage current L2 can be reduced, as indicated by arrow YJ1.

### Effects

As described above, according to the amplifier circuit 100a according to the first embodiment, by switching to the voltage divider resistor circuit 80 with high resistance values when in a standby mode, the biases can be controlled so as not to exceed the breakdown voltage in terms of DC, while suppressing the leakage current as well. When the voltage value of the power supply Vdd fluctuates, the biases are controlled so as not to exceed the breakdown voltage in terms of DC, while suppressing the leakage current as well. By suppressing the leakage current, optional power consumption can be prevented. Especially in a communication device powered by a battery, reducing power consumption can extend the battery life.

### Second Embodiment

A second embodiment will now be described. As described above, according to the amplifier circuit 100a, by switching to the voltage divider resistor circuit 80 with high resistance values when in a standby mode, leakage current can be suppressed while controlling the biases so as not to exceed the breakdown voltage in terms of DC. However, it is also conceivable that, when the voltage of the power supply Vdd fluctuates, the biases applied to the gates of the FETs 12 to FET 15 may fail to follow the changes, resulting in a delay. This delay may potentially lead to a temporary exceeding of the breakdown voltage. In addition, when transitioning from a standby mode to an operating state, there is a possibility that the biases applied to the gates of some FETs are not rapidly switched due to the influence of the low-pass filter described above. Accordingly, in the second embodiment, diodes are added.

### Configuration

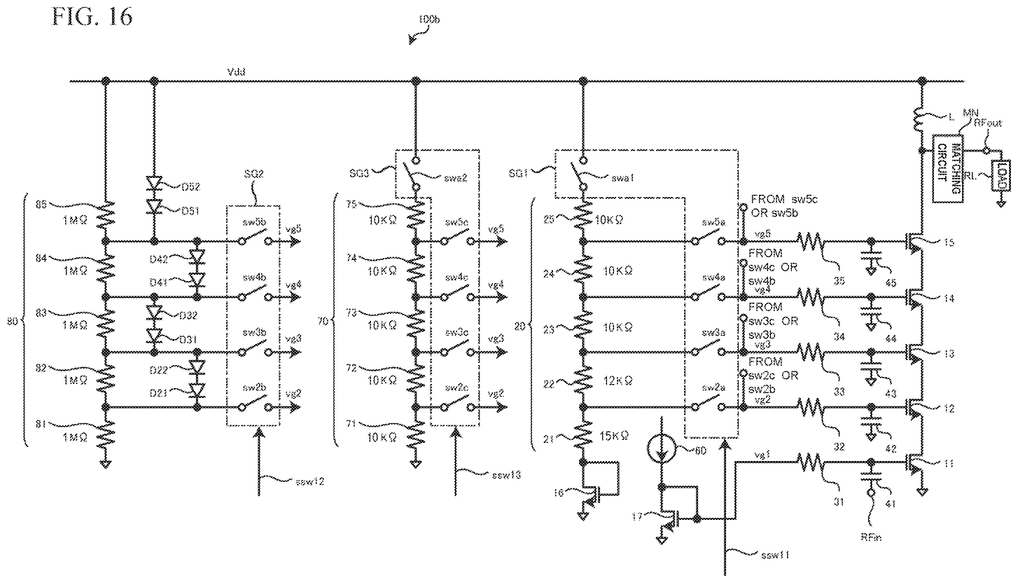

FIG. 16 is a circuit diagram illustrating an amplifier circuit 100b according to the second embodiment. The amplifier circuit 100b corresponds to the amplifier circuit 101 or 102 at the driver stage in FIG. 1. In FIG. 16, the amplifier circuit 100b is a configuration in which diodes are added to the amplifier circuit 100a described with reference to FIG. 3. As illustrated in FIG. 16, diodes are connected in parallel to each resistor in the second voltage divider resistor circuit 80. That is, diodes D21 and D22 are connected in parallel to the resistor 82. Diodes D31 and D32 are connected in parallel to the resistor 83. Diodes D41 and D42 are connected in parallel to the resistor 84. Diodes D51 and D52 are connected in parallel to the resistor 85. The anode of each of these diodes is connected to the power supply Vdd side. The cathode of each of these diodes is connected to the reference potential side. These diodes are first diodes connected in parallel to the resistors included in the voltage divider resistor circuit 80.

Here, in FIG. 16, the number of the first diodes connected in parallel to each resistor is two. In other words, diodes connected in series in two stages are connected in parallel to each resistor. Regarding the first diodes, the number of stages, i.e., the number of diodes connected in series, is adjusted so that the total threshold voltage (i.e., forward voltage VF) is less than or equal to the breakdown voltage of each FET. In other words, one first diode may be connected, or three or more first diodes may be connected.

Here, if the voltage value of the power supply Vdd is 5.5 [V], the potential difference due to the resistance of each stage of the voltage divider resistor circuit 80 is about 1.1 [V]. The threshold of the diodes connected in series in two stages is about 1.4 [V]. Therefore, the diodes connected in two stages do not turn on under normal circumstances. In contrast, the potential difference increases during transient response, and when the potential difference exceeds the threshold, the diodes connected in two stages turn on. Therefore, the potential difference can be limited by the diodes connected in two stages.

That is, for example, when the voltage of the power supply Vdd is at its maximum value within the operating range, if a voltage exceeding the voltage division ratio of the voltage divider resistor circuit 80 is applied, the diodes turn on. With the diodes turning on, this causes a rapid transition to a potential difference similar to the normal operating state. Additionally, instead of the diodes mentioned above, diode-connected FETs may be employed.

By the way, among the resistors 81 to 85 of the voltage divider resistor circuit 80, for the resistor 81 closest to the reference potential, no large potential is applied across both ends thereof. That is, no large potential is applied to the resistor 81 for generating the bias vg2. Thus, no diodes are connected in parallel to the resistor 81. This can limit the current flowing through all the diodes even when each diode turns on. Especially in the case where the circuit becomes hot, the threshold voltage may decrease, causing the diodes to remain in the on state. Even in such a case, the current flowing through the diodes can be suppressed. Therefore, the flow of large leakage current can be suppressed.

### Operation

As illustrated in FIG. 16, as countermeasures against voltage fluctuations of the power supply Vdd in a standby mode, the voltage divider resistor circuit 80 is provided, including resistors with resistance values greater than those of the resistors in the voltage divider resistor circuit 20, and diodes are further connected in parallel to each resistor. Therefore, with the diodes turning on, this causes a rapid transition to a potential difference similar to the normal operating state.

### Effects

In a standby mode where amplification operation is not performed, it is possible to control the bias applied to the gate of each FET, following the voltage fluctuations of the power supply Vdd, while suppressing leakage current as well, thereby realizing the operation not exceeding the breakdown voltage. By suppressing the leakage current, optional power consumption can be prevented. Especially in a communication device powered by a battery, reducing power consumption can extend the battery life. In addition, since the leakage current can be suppressed simply by adding diodes, it is optional to perform complicated control for suppressing the leakage current.

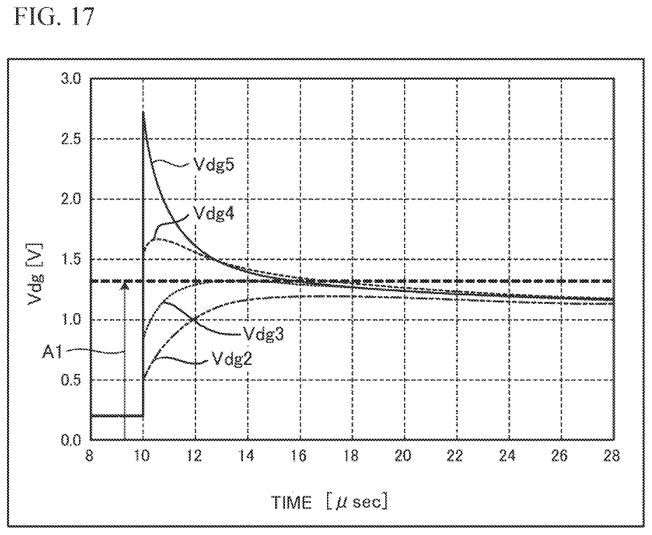

Here, FIG. 17 is a diagram illustrating simulation results for the case where the diodes in FIG. 16 are not connected. In FIG. 17, the horizontal axis indicates the time [μs], and the vertical axis indicates the value [V] of the drain-gate voltage Vdg. In FIG. 17, the voltage Vdg2 is the drain-gate voltage of an FET 12, the voltage Vdg3 is the drain-gate voltage of an FET 13, the voltage Vdg4 is the drain-gate voltage of an FET 14, and the voltage Vdg5 is the drain-gate voltage of an FET 15. In FIG. 17, as the voltage value of the power supply Vdd changes instantaneously from 1.0 [V] to 5.5 [V], the peak value of the drain-gate voltage is about 2.5 [V], and the time exceeding the unbroken area A1 is about 6 [μs].

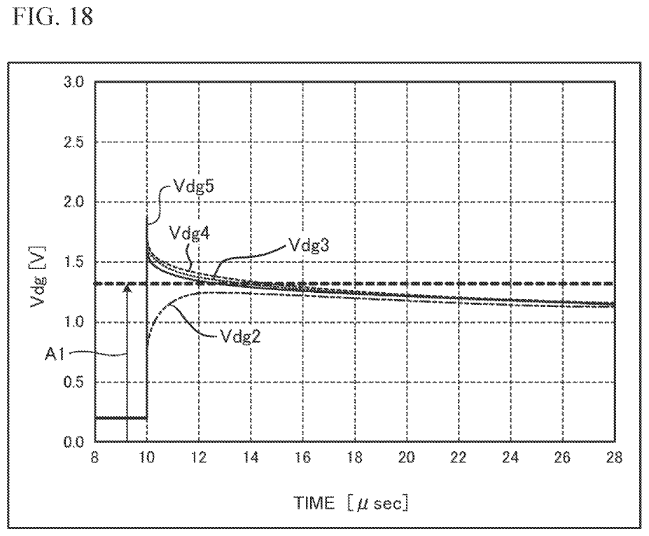

In the meantime, FIG. 18 is a diagram illustrating the operation in the case where diodes are connected as in FIG. 16. In FIG. 18 the horizontal axis indicates the time [μs], and the vertical axis indicates the value [V] of the drain-gate voltage Vdg. In FIG. 18, as the voltage value of the power supply Vdd changes from 1.0 [V] to 5.5 [V] during 10 [nsec], the peak value of the drain-gate voltage is about 1.9 [V], and the time exceeding the unbroken area A1 is about 4 [μs]. In this way, the peak value of the drain-gate voltage can be suppressed, and the time exceeding the unbroken area A1 can be shortened.

That is, the delay in the rise of the gate bias can be improved by placing diodes in parallel to each resistor in the voltage divider resistor circuit 80. For example, the case will be considered in which the potential difference across both ends of the resistor 85 is designed to be 1.1 [V] in terms of DC when the power supply Vdd is 5.5 [V]. In this case, when the power supply Vdd rises, the rise of the gate bias vg5 may be delayed and the potential difference across both ends of the resistor 85 may temporarily be 1.8 [V]. Here, if diodes are connected in parallel, when the potential difference across both ends of the resistor 85 becomes greater than the total forward voltage (VF) of the diodes connected in series, the diodes turn on and supply current. Therefore, the potential difference across both ends of the resistor 85 can be reduced to about the total VF of the diodes connected in series.

The number of diodes connected in series is determined to satisfy, for example, the following relationship. That is, the potential difference across both ends of each resistor when the power supply Vdd is at its maximum<the number of diodes connected in series×VF<the maximum rating of the FET. Although the orientation of the diodes has been set in the direction of taking countermeasures against the rapid rise of the power supply Vdd, the orientation of the diodes may be reversed, as described below. By reversing the orientation of the diodes, if the power supply Vdd suddenly drops, countermeasures can be taken on the same principle by placing the reverse-oriented diodes.

### Third Embodiment

A third embodiment will now be described.

### Configuration

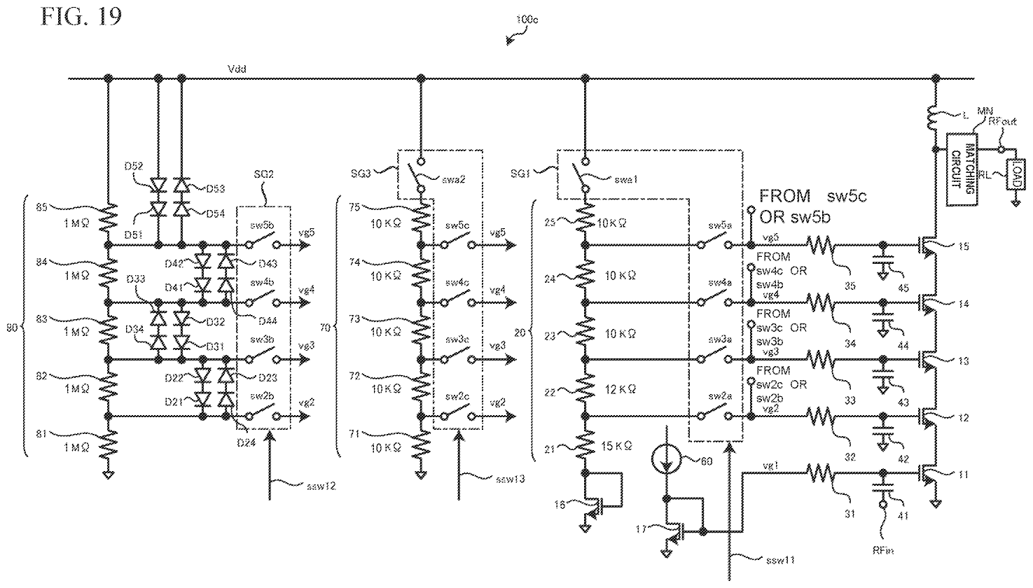

FIG. 19 is a circuit diagram illustrating an amplifier circuit 100c according to the third embodiment. The amplifier circuit 100c corresponds to the amplifier circuit 101 or 102 at the driver stage in FIG. 1. In FIG. 19, the amplifier circuit 100c is a configuration in which diodes are further added to the amplifier circuit 100b described with reference to FIG. 16, with the diodes connected bidirectionally. As illustrated in FIG. 19, diodes are further connected in parallel to each of the resistors in the second voltage divider resistor circuit 80. That is, diodes D23 and D24 are connected in parallel to the resistor 82. Diodes D33 and D34 are connected in parallel to the resistor 83. Diodes D43 and D44 are connected in parallel to the resistor 84. Diodes D53 and D54 are connected in parallel to the resistor 85. The anode of each of these diodes is connected to the reference potential side. The cathode of each of these diodes is connected to the power supply Vdd side. These diodes are second diodes connected in parallel to the resistors included in the voltage divider resistor circuit 80.

### Operation

By further connecting the second diodes in parallel to each resistor in the second voltage divider resistor circuit 80, in the case where the voltage value of the power supply Vdd fluctuates, if a voltage exceeding the threshold of the diodes is applied, the diodes turn on, and this causes a rapid transition to a potential difference similar to the normal operating state. Therefore, during the transition from a high voltage value to a low voltage value, i.e., during the drop, it is possible to suppress delays caused by the time constant.

### Effects

As in the case of the second embodiment, by suppressing the leakage current, optional power consumption can be suppressed. Especially in a communication device powered by a battery, reducing power consumption can extend the battery life. Also, by further connecting the second diodes in parallel to each resistor in the second voltage divider resistor circuit 80, when the power supply Vdd transitions from a high voltage value to a low voltage value, i.e., during the drop, it is possible to suppress delays caused by the time constant.

### Fourth Embodiment

A fourth embodiment will now be described.

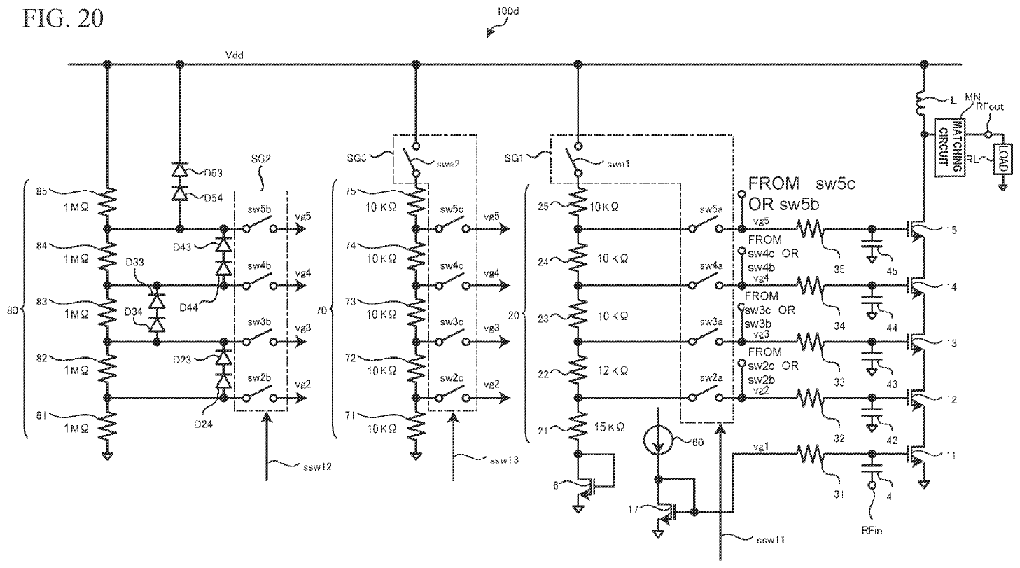

FIG. 20 is a circuit diagram illustrating an amplifier circuit 100d according to the fourth embodiment. The amplifier circuit 100d corresponds to the amplifier circuit 101 or 102 at the driver stage in FIG. 1. In FIG. 20, the amplifier circuit 100d is a configuration in which the orientation of each diode of the amplifier circuit 100b is reversed.

As illustrated in FIG. 20, diodes are connected in parallel to each resistor in the second voltage divider resistor circuit 80. That is, diodes D23 and D24 are connected in parallel to the resistor 82. Diodes D33 and D34 are connected in parallel to the resistor 83. Diodes D43 and D44 are connected in parallel to the resistor 84. Diodes D53 and D54 are connected in parallel to the resistor 85. The anode of each of these diodes is connected to the reference potential side. The cathode of each of these diodes is connected to the power supply Vdd side. These diodes are second diodes connected in parallel to the resistors included in the voltage divider resistor circuit 80. It can also be said that the amplifier circuit 100d illustrated in FIG. 20 is a configuration in which some of the diodes in the amplifier circuit 100c described with reference to FIG. 19 are removed.

### Operation

In the case where the voltage value of the power supply Vdd fluctuates, if a voltage exceeding the threshold of the diodes is applied, the diodes turn on, and this causes a rapid transition to a potential difference similar to the normal operating state. Therefore, during the transition from a high voltage value to a low voltage value, i.e., during the drop, it is possible to suppress delays caused by the time constant.

### Effects

As in the case of the second embodiment, by suppressing the leakage current, optional power consumption can be suppressed. Especially in a communication device powered by a battery, reducing power consumption can extend the battery life. Also, by connecting the second diodes in parallel to each resistor in the second voltage divider resistor circuit 80, when the power supply Vdd transitions from a high voltage value to a low voltage value, i.e., during the drop, it is possible to suppress delays caused by the time constant.

### Power Amplifier Circuit and Communication Device

As described with reference to FIG. 1, any of the above-described amplifier circuits 100a to 100c may be used as a driver-stage amplifier circuit, and a power-stage amplifier circuit may be further provided, with the output of the driver-stage amplifier circuit serving as input, thereby forming a power amplifier circuit. In doing so, a power amplifier circuit suitable for use in a communication device or the like can be realized.

As described with reference to FIG. 1, a plurality of power amplifier circuits each including a driver-stage amplifier circuit and a power-stage amplifier circuit may be provided in or on a communication device, and these power amplifier circuits may be selectively operated. In the communication device 1000 illustrated in FIG. 1, two power amplifier circuits M1 and H1 are provided in or on the communication device. As described above, the power amplifier circuits M1 and H1 are formed as separate PA modules. Then, the power amplifier circuits M1 and H1 selectively perform amplification operation according to the voltage supplied by the common power supply Vdd. With such a configuration, a communication device that can suppress power consumption due to leakage current can be realized.

With respect to the description of the claims, the present disclosure can take the following aspects.
<1> An amplifier circuit including:
an input terminal to which a signal to be amplified is input;
a first FET having a gate to which the signal input to the input terminal is applied;
a second FET connected, together with the first FET, between a power supply and a reference potential;
an output terminal provided between the second FET and a load to output an amplified signal;
a first voltage divider resistor circuit that divides a potential difference between the power supply and the reference potential, and generates a bias to be applied to a gate of the second FET;
a first switch element provided between the first voltage divider resistor circuit and the power supply and for turning on/off an electrical connection between the power supply and the first voltage divider resistor circuit;
a second voltage divider resistor circuit that divides a potential difference between the power supply and the reference potential, and generates a bias to be applied to the gate of the second FET;
a third voltage divider resistor circuit that divides a potential difference between the power supply and the reference potential, and generates a bias to be applied to the gate of the second FET; and
a second switch element provided between the third voltage divider resistor circuit and the power supply and for turning on/off an electrical connection between the power supply and the third voltage divider resistor circuit,
wherein the first FET and the second FET have their adjacent drains and sources connected,
a resistance value of each of resistors included in the second voltage divider resistor circuit is greater than a resistance value of each of resistors included in the first voltage divider resistor circuit,
a resistance value of each of resistors included in the third voltage divider resistor circuit is less than the resistance value of each of the resistors included in the second voltage divider resistor circuit, and
a voltage division ratio of the resistors included in the second voltage divider resistor circuit and a voltage division ratio of the resistors included in the third voltage divider resistor circuit are identical.
<2> The amplifier circuit according to <1>, wherein:
when transitioning from a state in which amplification operation is performed to a standby state in which amplification operation is not performed, the first voltage divider resistor circuit and the power supply are electrically disconnected by turning off the first switch element, and the third voltage divider resistor circuit and the power supply are electrically connected by turning on the second switch element; and
after transitioning to the standby state, after a certain period of time has further elapsed, the third voltage divider resistor circuit and the power supply are electrically disconnected by turning off the second switch element.
<3> The amplifier circuit according to <1> or <2>, further including:
a third switch element provided between the second voltage divider resistor circuit and the second FET,
wherein a bias is supplied from the second voltage divider resistor circuit to the second FET by way of the third switch element, and
the third switch element
   turns off when the first switch element turns on, and
   turns on when the first switch element turns off.
<4> The amplifier circuit according to any one of <1> to <3>, further including:
a fourth switch element provided between the first voltage divider resistor circuit and the second FET; and
a fifth switch element provided between the third voltage divider resistor circuit and the second FET,
wherein a bias is supplied from the first voltage divider resistor circuit to the second FET by way of the fourth switch element,
a bias is supplied from the third voltage divider resistor circuit to the second FET by way of the fifth switch element,
the fourth switch element
   turns on when the first switch element turns on, and
   turns on when the first switch element turns off, and
the fifth switch element
   turns on when the second switch element turns on, and
   turns on when the second switch element turns off.
<5> The amplifier circuit according to any one of <1> to <4>, further including:
a first diode connected in parallel to a resistor included in the second voltage divider resistor circuit,
wherein an anode of the first diode is connected to the power supply side of the resistor, and
a cathode of the first diode is connected to the reference potential side of the resistor.
<6> The amplifier circuit according to <5>, wherein:
the first diode is not connected to a resistor closest to the reference potential side, among the resistors included in the second voltage divider resistor circuit.
<7> The amplifier circuit according to any one of <1> to <6>, further including:
a second diode connected in parallel to a resistor included in the second voltage divider resistor circuit,
wherein an anode of the second diode is connected to the reference potential side of the resistor, and
a cathode of the second diode is connected to the power supply side of the resistor.
<8> The amplifier circuit according to any one of <1> to <7>, wherein:
the first switch element turns off when amplification operation by the first FET and the second FET is not performed.
<9> The amplifier circuit according to any one of <1> to <8>, wherein a voltage value of the power supply fluctuates.
<10> A power amplifier circuit in which the amplifier circuit according to any one of <1> to <9> serves as a driver-stage amplifier circuit, the power amplifier circuit further including a power-stage amplifier circuit, with output of the driver-stage amplifier circuit serving as input.
<11> The power amplifier circuit according to <10>, wherein the power-stage amplifier circuit is configured by a bipolar transistor.
<12> A communication device including a plurality of the power amplifier circuits according to <11>, wherein the plurality of the power amplifier circuits selectively perform amplification operation according to a voltage supplied by a common power supply.

What is claimed is:

1. An amplifier circuit comprising:
an input terminal to which a signal is input;
a first field effect transistor (FET) having a gate to which the signal input to the input terminal is applied;
a second FET connected, together with the first FET, between a power supply and a reference potential;
an output terminal between the second FET and a load, and that is configured to output an amplified signal;
a first voltage divider resistor circuit configured to divide a potential difference between the power supply and the reference potential, and to generate a first bias applied to a gate of the second FET;
a first switch between the first voltage divider resistor circuit and the power supply, and configured to switch a first electrical connection between the power supply and the first voltage divider resistor circuit;
a second voltage divider resistor circuit configured to divide the potential difference between the power supply and the reference potential, and to generate a second bias applied to the gate of the second FET;
a third voltage divider resistor circuit configured to divide the potential difference between the power supply and the reference potential, and to generate a third bias applied to the gate of the second FET; and
a second switch between the third voltage divider resistor circuit and the power supply, and configured to switch a second electrical connection between the power supply and the third voltage divider resistor circuit,
wherein a source of the first FET is connected to a drain of the second FET,
wherein a resistance value of each of a plurality of resistors in the second voltage divider resistor circuit is greater than a resistance value of each of a plurality of resistors in the first voltage divider resistor circuit,
wherein a resistance value of each of a plurality of resistors in the third voltage divider resistor circuit is less than the resistance value of each of the plurality of resistors in the second voltage divider resistor circuit, and
wherein a voltage division ratio of the resistors in the second voltage divider resistor circuit is the same as a voltage division ratio of the resistors in the third voltage divider resistor circuit.

2. The amplifier circuit according to claim 1,
wherein when transitioning from a state in which amplification operation is performed to a standby state in which amplification operation is not performed, the first switch is configured to disconnect the first electrical connection, and the second switch is configured to connect the second electrical connection, and
wherein a predetermined time after transitioning to the standby state, the second switch is configured to disconnect the second electrical connection.

3. The amplifier circuit according to claim 1, further comprising:
a third switch between the second voltage divider resistor circuit and the second FET,
wherein the second bias generated by the second voltage divider resistor circuit is supplied to the second FET by way of the third switch, and
the third switch element is configured to disconnect the second voltage divider resistor circuit from the second FET when the first switch connects the first electrical connection, and is configured to connect the second voltage divider resistor circuit to the second FET when the first switch disconnects the first electrical connection.

4. The amplifier circuit according to claim 1, further comprising:
a fourth switch between the first voltage divider resistor circuit and the second FET; and
a fifth switch between the third voltage divider resistor circuit and the second FET,
wherein the first bias generated by the first voltage divider resistor circuit is supplied to the second FET by way of the fourth switch,
wherein the third bias generated by the third voltage divider resistor circuit is supplied to the second FET by way of the fifth switch,
wherein the fourth switch is configured to connect the first voltage divider resistor circuit to the second FET when the first switch connects the first electrical connection, and is configured to disconnect the first voltage divider resistor circuit from the second FET when the first switch disconnects the first electrical connection, and
wherein the fifth switch is configured to connect the third voltage divider resistor circuit to the second FET when the second switch connects the second electrical connection, and is configured to disconnect the third voltage divider resistor circuit from the second FET when the second switch element disconnects the second electrical connection.

5. The amplifier circuit according to claim 1, further comprising:
a first diode connected in parallel to a resistor in the second voltage divider resistor circuit,
wherein an anode of the first diode is connected to a power supply side of the resistor, and
wherein a cathode of the first diode is connected to a reference potential side of the resistor.

6. The amplifier circuit according to claim 5, wherein the first diode is not connected to the resistor in the second voltage divider resistor circuit that is closest to the reference potential.

7. The amplifier circuit according to claim 1, further comprising:
a second diode connected in parallel to a resistor in the second voltage divider resistor circuit,
wherein an anode of the second diode is connected to a reference potential side of the resistor, and
wherein a cathode of the second diode is connected to a power supply side of the resistor.

8. The amplifier circuit according to claim 1, wherein the first switch element is configured to disconnect the first electrical connection when an amplification operation is not performed by the first FET and the second FET.

9. The amplifier circuit according to claim 1, wherein a voltage value of the power supply fluctuates.

10. A power amplifier comprising:
a driver-stage amplifier circuit comprising the amplifier circuit according to claim 1; and
a power-stage amplifier circuit,
wherein the amplified signal output from the output terminal of the driver-stage amplifier circuit is input to the power-stage amplifier circuit.

11. The power amplifier circuit according to claim 10, wherein the power-stage amplifier circuit comprises a bipolar transistor.

12. A communication device comprising a plurality of the power amplifiers according to claim 11, wherein the plurality of the power amplifiers are configured to selectively perform an amplification operation according to a voltage supplied by a common power supply.
